(19) United States
(12) Patent Application Publication
(10) Pub. No.: US 2005/0193946 A1
(43) Pub. Date: Sep. 8, 2005

(54) Apparatus and method for preventing corrosion of a vacuum gauge

(75) Inventors: Chin-Lung Wu, Tainan Hsien (TW); Li-Wei Ho, Taipei (TW)

Correspondence Address: SQUIRE, SANDERS & DEMPSEY L.L.P, 600 HANSEN WAY, PALO ALTO, CA, 94304-1043, US

(73) Assignee: SiS Microelectronics Corporation, Hsin-Chu (TW)

(21) Appl. No.: 10/794,016

(22) Filed: Mar. 5, 2004

(51) Int. Cl. C23C 16/00; C23F 1/00

(52) U.S. Cl. 118/715; 156/345.29; 118/733

(57) ABSTRACT

A vacuum process apparatus for preventing corrosion of a vacuum gauge is disclosed. The apparatus includes a process chamber used to proceed a vacuum process reaction. A vacuum gauge is connected to the process chamber. A protective gas source without water vapor which supplies a protective gas without water vapor into the process chamber to break vacuum in the process chamber after the vacuum process reaction within the process chamber is over. An isolation device between the process chamber and the vacuum gauge is actuated to isolate the process chamber from the vacuum gauge in an atmospheric pressure state caused by the protective gas without water vapor to avoid a pressure differential between the process chamber and the vacuum gauge.

### BACKGROUND OF THE INVENTION

1. Field of the Invention

The present invention relates to a method for preventing corrosion of a vacuum gauge, and more particularly to the method for preventing corrosion of a vacuum gauge utilized in semiconductor manufacturing apparatuses.

2. Description of the Prior Art

Many processes for fabricating semiconductor devices are proceeded in a condition of a low pressure or a glow discharge. For examples, they include low pressure chemical vapor deposition (LPCVD), plasma enhanced chemical vapor deposition (PECVD), evaporation, epitaxy, ion implantation, sputtering deposition, dry etching and so on. Many apparatuses for proceeding these processes utilize a vacuum system to achieve the demanded condition of these processes.

A vacuum system used to form a thin film deposition, which depicted in FIG. 1, includes a process chamber 10, a load lock chamber 12, a process gas 14, a susceptor 16, a vacuum gauge 18, a roughing pump 20, a high vacuum pump 22, a throttle valve 24, a valve 26 and so on, herein a purpose of the load lock chamber 12 is not only to keep a certain vacuum degree of the process chamber 10 to reduce contaminants but also to shorten a cycle time of a process. The roughing pump 20, usually being a mechanical pump, is used to evacuate the load lock chamber 12 after a wafer 28 is positioned within the load lock chamber 12. When the vacuum degree of the load lock chamber 12 reaches a certain degree, a valve 26 between the load lock chamber 12 and the process chamber 10 will be opened. The wafer 28 is transmitted from the load lock chamber 12 to the susceptor 16 of the process chamber 10. Before the transmission of the wafer 28, the process chamber 10 should be evacuated to a certain vacuum degree by another roughing pump 20 accompanying with a gas ballast (not shown). After the transmission of the wafer 28, the high vacuum pump 22, such as a diffusion pump, a turbo molecular pump, a cryo pump or a Roots blower, is pumped to a higher vacuum degree of the process chamber 10. Next, the wafer 28 is heated to a deposition temperature or a temperature which the process needs. A process gas 14 is supplied to flow into the process chamber 10 through a mass flow controller (MFC) 34. The vacuum degree measured by the vacuum gauge 18, such as a capacitance manometer, a thermocouple gauge or an ionization gauge, is used to monitor the pressure within the process chamber 10. When the process is over, the process gas 14 or by-products are exhausted by the roughing pump 20 through an exhaust gas abatement equipment, such as a burn box 30, to clean a portion of the process gas 14 or by-products with combustible or toxicity. Finally, the process gas 14 or by-products after safety treatment are exhausted 32 out of the vacuum system used to form the thin film deposition.

Among the vacuum system, except pumps, there are other important components, such as a vacuum gauge, a tube and a valve, herein how to choose an adapted vacuum gauge should be considered about an ultimate vacuum degree of the process chamber. In vacuum technology, the vacuum degree is divided into five sections: a rough vacuum, a medium vacuum, a high vacuum, a very high vacuum, and an ultra high vacuum. There is different requirements of different vacuum degrees for different processes, such as both of the processes for sputtering deposition and dry etching are in the vacuum degree between the rough vacuum and the medium vacuum, and the vacuum degree of the ion implantation is in the high vacuum.

In a semiconductor process, the process gas which is reactive to the wafer is used to form a thin film or to etch a surface of the wafer. Products formed by the process gas are not only formed on the wafer but also formed on a wall of the process chamber. If these products have a poor adhesion, a portion of them will fall off to form particles. Then, a yield of the wafer will drop down. Maintenance technicians should proceed a preventive maintenance (PM) for apparatuses periodically to avoid too many depositions formed on the wall of the process chamber. Although the process gas or the by-products will be exhausted out of the process chamber by the vacuum pump after the process is over. There is still a residual of the process gas to adsorb on the wall of the process chamber, tubes, and the vacuum gauge which is in charge of detecting a pressure of the process chamber. When maintenance technicians proceed a preventive maintenance (PM) for an apparatus under an atmospheric condition, the residual process gas which contains fluorine or chlorine is reacted with atmospheric water vapor to produce a corrosive material, such as acid. The corrosive material will corrode the vacuum gauge to shorten a life of the vacuum gauge and to shift a value of a measurement of the vacuum gauge.

A design of the apparatus with a pneumatically operated valve added on the tube between the vacuum gauge and the process chamber is used to avoid a foregoing problem. Before the preventive maintenance, the pneumatically operated valve is closed to isolate the vacuum gauge in a vacuum state. Then the vacuum is broken in the process chamber. Now an isolation device for protecting the vacuum gauge usually is the pneumatically operated valve which is controlled by a signal of a pressure sensor of the process chamber. When a pressure of the process chamber is higher than a setting value, such as 10 torr, the pressure sensor will send a signal to the pneumatically operated valve to be closed. At this time, an inner space of the vacuum gauge is in the vacuum state about 10 torr. When the pressure of the process chamber is equivalent to an atmospheric pressure about 760 torr, the pressure sensor will send an another signal to the apparatus to show the pressure of the process chamber. Next, the maintenance technicians open a valve of the process chamber to proceed a preventive maintenance for the apparatus. Because the pressure of the process chamber is about 760 torr and the pressure of the inner space of the vacuum gauge is about 10 torr, there is a pressure differential for atmospheric water vapor to penetrate into the inner space of the vacuum gauge. Moreover, if the process gas or by-products is adsorbed on a valve seat of the pneumatically operated valve to form a deposition on it, the pneumatically operated valve can not seal the valve seat completely. The atmospheric water vapor directly flows into the inner space of the vacuum gauge through a void between the pneumatically operated valve and the valve seat to generate an acid to corrode the vacuum gauge.

Nowadays some apparatuses made by some semiconductor equipment manufacturers are designed without isolation devices and the others are designed with isolation devices. The life of the vacuum gauge of the apparatuses without isolation devices usually can not reach a half of the life of the vacuum gauge of the apparatuses with isolation devices. Besides, although the other apparatuses with isolation devices can protect the vacuum gauge from corrosion within the vacuum state due to the pneumatically operated valve, there is also a risk of leaking for the pneumatically operated valve due to a deposition on it. The design of the apparatus with an isolation device or not all has a risk of leaking the atmospheric water vapor to react with the process gas or by-products adsorbed on the vacuum gauge to form a corrosive material. The corrosive material will corrode the vacuum gauge to shorten the life of the vacuum gauge and to shift the valve of the measurement of the vacuum gauge.

### SUMMARY OF THE INVENTION

Accordingly, both of the traditional design without adopting an isolation device and the new design with adopting a pneumatically operated valve have a problem of generating a corrosion on the vacuum gauge, thereby it is one objective of the present invention to provide a method for preventing corrosion of the vacuum gauge. A characteristic of the method is to keep the vacuum gauge under a protective gas without water vapor. Because the protective gas without the water vapor can not react with the residual process gas absorbed on the vacuum gauge, the purpose of the preventing corrosion of the vacuum gauge is achieved.

It is another objective of the present invention to add a manually operated valve to prevent corrosion of the vacuum gauge. The manually operated valve is an isolation device which has many advantages, such as a simple structure, a cheaper price, and a easy maintenance, and can be directly added on the tube between the vacuum gauge and the process chamber to reach the better effect of preventing corrosion of the vacuum gauge than the pneumatically operated valve added on the present apparatus.

It is another objective of the present invention to use a theory of equivalent pressure to prevent corrosion of the vacuum gauge. The characteristic of the present invention is to make the pressure of the inner space of the vacuum gauge equal to the atmospheric pressure outside the isolation device. It can avoid the atmospheric water vapor flowing into the vacuum gauge due to a leakage of the isolation device.

In order to achieve above purposes, a vacuum process apparatus for preventing corrosion of a vacuum gauge is disclosed. The apparatus includes a process chamber used to proceed a vacuum process reaction. A vacuum gauge is connected to the process chamber. A protective gas source without water vapor which supplies a protective gas without water vapor into the process chamber to break vacuum in the process chamber after the vacuum process reaction within the process chamber is over. An isolation device between the process chamber and the vacuum gauge is actuated to isolate the process chamber from the vacuum gauge in an atmospheric pressure state caused by the protective gas without water vapor to avoid a pressure differential between the process chamber and the vacuum gauge.

### BRIEF DESCRIPTION OF THE DRAWINGS

The present invention can be best understood through the following description and accompanying drawings wherein:

FIG. 1 is a schematic diagram of a vacuum system for forming a thin film deposition in the prior art.

FIG. 2 is a schematic diagram of the embodiment of the present invention.

FIG. 3 is a schematic diagram of the manually operated valve of the present invention.

FIG. 4 is a schematic diagram of the pneumatically operated valve of the present invention.

FIG. 5 is another schematic diagram of the embodiment of the present invention.

FIG. 6 is a schematic flow chart of the embodiment of the present invention.

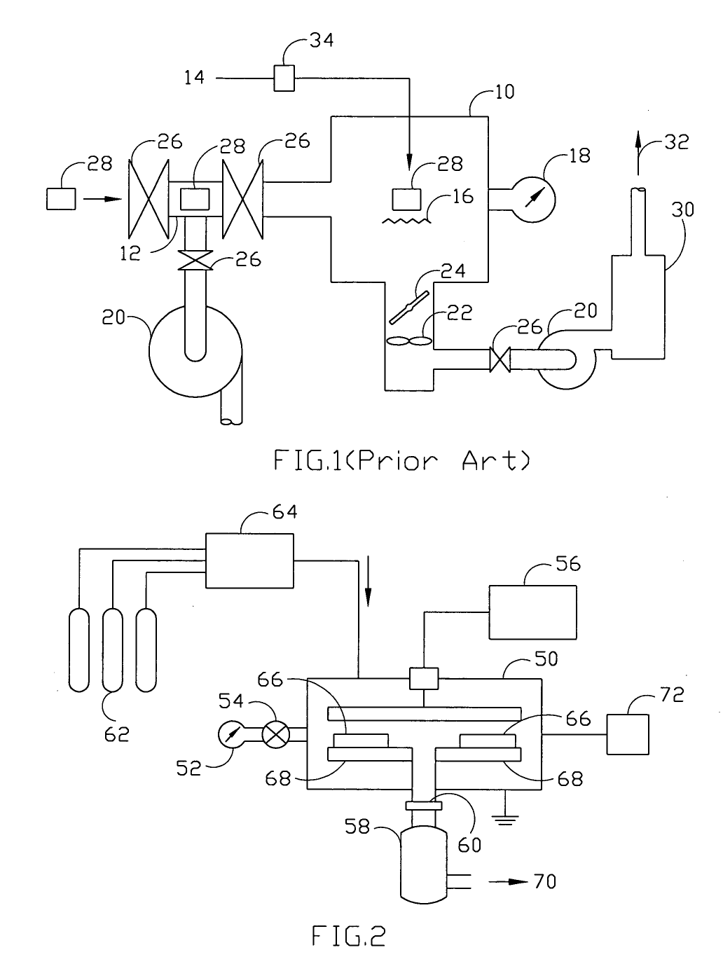

### DESCRIPTION OF THE PREFERRED EMBODIMENT

Some embodiments of the present invention have detailed descriptions below. However, except for the detailed descriptions, the present invention can have a broad use in other embodiments, and the scope of the present invention can not be defined by this preferred embodiment, but by the appended claims.

Furthermore, in order to supply a more clear description and more understanding of the present invention, irrelative detailed portions are not completely drawn. Then, the components of the present invention are not shown to scale. Some dimensions are exaggerated to the related components to provide a more clear description and comprehension of the present invention.

A vacuum process apparatus for preventing corrosion of a vacuum gauge is disclosed. The apparatus includes a process chamber used to proceed a vacuum process reaction. A vacuum gauge is connected to the process chamber. A protective gas source without water vapor which supplies a protective gas without water vapor into the process chamber to break vacuum in the process chamber after the vacuum process reaction within the process chamber is over. An isolation device between the process chamber and the vacuum gauge is actuated to isolate the process chamber from the vacuum gauge in an atmospheric pressure state caused by the protective gas without water vapor to avoid a pressure differential between the process chamber and the vacuum gauge.

Referring to FIG. 2, the preferred embodiment of the present invention is a plasma etching apparatus added an isolation device, such as a manually operated valve, to isolate the vacuum gauge from the process chamber. The plasma etching apparatus includes a process chamber 50, a capacitance manometer 52, a manually operated valve 54, a radio frequency (RF) generator 56, a vacuum pump 58, a throttle valve 60, a reactive gas source 62, a mass flow controller 64 and a protective gas source without water vapor 72. Firstly, a substrate, such as a wafer 66, is positioned on an electrode 68 through a valve (not shown) of the process chamber 50 and the valve (not shown) is closed later. The vacuum pump 58 is pumped to exhaust the gas out of the process chamber 50 until to reach a working pressure of a plasma etching process. The working pressure of the plasma etching process is about 0-10 torr. The reactive gas of the reactive gas source 62, such as chlorine gas (Cl₂), hydrogen bromide (HBr), and born trichloride (BCl₃), is added into the process chamber 50. Next, the RF generator 56 is started to generate an electrical field to make the reactive gas produce a plasma (not shown). The plasma will etch the wafer 66 anisotropically. Both of the reactive gas and the vacuum pump 58 are kept on supplying and pumping. Because parts of the reactive gas and by-products are toxic, all of the reactive gas and by-products should be exhausted out of the process chamber 50 after the plasma etching process is over. Meanwhile, both of the mass flow controller 64 and the RF generator 56 should be turned off. Next, the protective gas of the protective gas source without water vapor 72, such as nitrogen gas (N₂), is filled into the process chamber 50 to break vacuum in the process chamber 50. Finally, the valve (not shown) of the process chamber is opened and the wafer 66 is unloaded. Herein the nitrogen gas is filled into the process chamber 50 to break vacuum in the process chamber 50, the inner space of the vacuum gauge 52 is full of the nitrogen gas with equivalent pressure to the process chamber 50 at the same time. When the pressure of the nitrogen gas of the process chamber 50 is equivalent to the atmospheric pressure, a pressure sensor (not shown) of the process chamber 50 will send a signal to a controller (not shown) of the apparatus to show the present pressure on a display device (not shown). Next, one of the features of the present invention, the manually operated valve 54 is closed right now to isolate the vacuum gauge 52 from the process chamber 50. Then the valve of the process chamber 50 is opened to proceed the preventive maintenance of the process chamber 50. Because the pressure of the inner space of the vacuum gauge 52 is equivalent to the pressure of the process chamber 50, the atmospheric water vapor of the process chamber 50 will not flow into the inner space of the vacuum gauge 52 due to a pressure differential between the vacuum gauge 52 and the process chamber 50. The purpose of preventing corrosion of the vacuum gauge 52 can be attained.

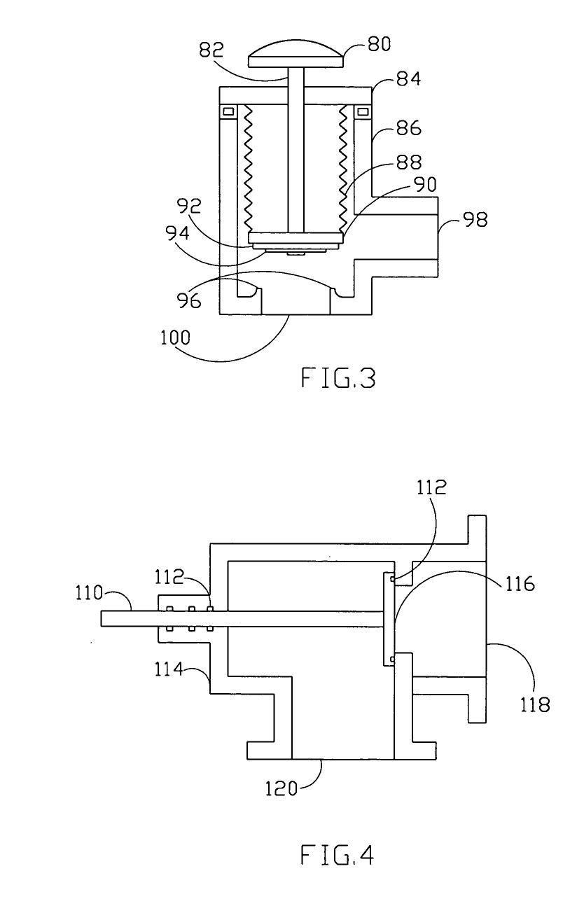

In the other aspect, the other of the features of the present invention, the manually operated valve 54, depicted in FIG. 3, is preferred to use to be an isolation device, herein it includes a knob 80, a valve steam 82, a bonnet 84, a housing 86, a bellows 88, a disk 90, a gasket 92, a spacer 94, a valve seat 96, a process chamber port 98, and a vacuum gauge port 100. The gasket 92 could be a flexible gasket, such as an O-ring. The O-ring made by different materials has different effects of anti-corrosion to different process gases. An effect of cost down is reached by adopting the O-ring made of adaptive materials with respect to the process gas used in the apparatus.

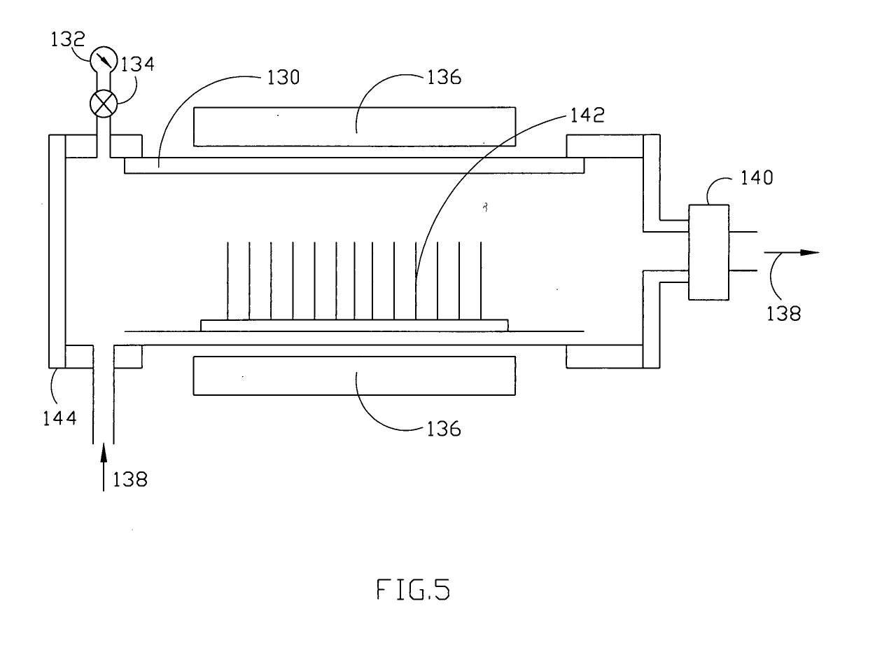

In addition to considering an automatic control, the manually operated valve 54 could be replaced by a pneumatically operated valve. Referring to FIG. 4, the pneumatically operated valve includes a valve stem 110, a gasket 112, a bonnet 114, a disk 116, a process chamber port 118, and a vacuum gauge port 120, herein the valve stem 110 is sealed by double O-rings or bellows. Alternatively, the manually operated valve could also be replaced by a solenoid valve to meet the need of the design.

Referring to FIG. 5, the other preferred embodiment of the present invention is a low pressure chemical vapor deposition apparatus added a manually operated valve to isolate the vacuum gauge from the process chamber. The low pressure chemical vapor deposition apparatus which is usually used to form a polysilicon, a silicon dioxide, and a silicon nitride includes a process chamber 130, a capacitance manometer 132, a manually operated valve 134, a heater 136, a reactive gas 138, and a vacuum pump 140. Firstly, a wafer 142 is loaded in the process chamber 130 through a load/unload door 144 and the load/unload door 144 is closed later. The vacuum pump 140, such as Roots blower, is used to exhaust the gas out of the process chamber 130 until to reach a working pressure of the low pressure chemical vapor deposition process. The working pressure of the low pressure chemical vapor deposition process is about 0.25-2 torr. Meanwhile, the wafer 142 is heated to a temperature about 300-900° C. by the heater 136 and the reactive gas 138 is added into the process chamber 130. The flow rate of the reactive gas 138 is about 100-1000 standard cubic centimeters per minute (sccm). After the low pressure chemical vapor deposition process is over, the reactive gas 138 and by-products are exhausted out of the process chamber 130. Next, nitrogen gas (not shown) without water vapor is purged into the process chamber 130 to break vacuum in the process chamber 130 until a pressure sensor of the process chamber 130 shows the pressure value about 760 torr. Finally, the manually operated valve 134 is closed to isolate the vacuum gauge 132 from the process chamber 130. Then the load/unload door 144 of the process chamber 130 is opened to unload the wafer 142 and the preventive maintenance of the process chamber 130 can be proceeded by the maintenance technicians later. Because the pressure of the inner space of the vacuum gauge 132 is equivalent to the pressure of the process chamber 130, the atmospheric water vapor of the process chamber 130 will not flow into the inner space of the vacuum gauge 132 due to a pressure differential between the vacuum gauge 132 and the process chamber 130 to reach the effect of preventing corrosion of the vacuum gauge.

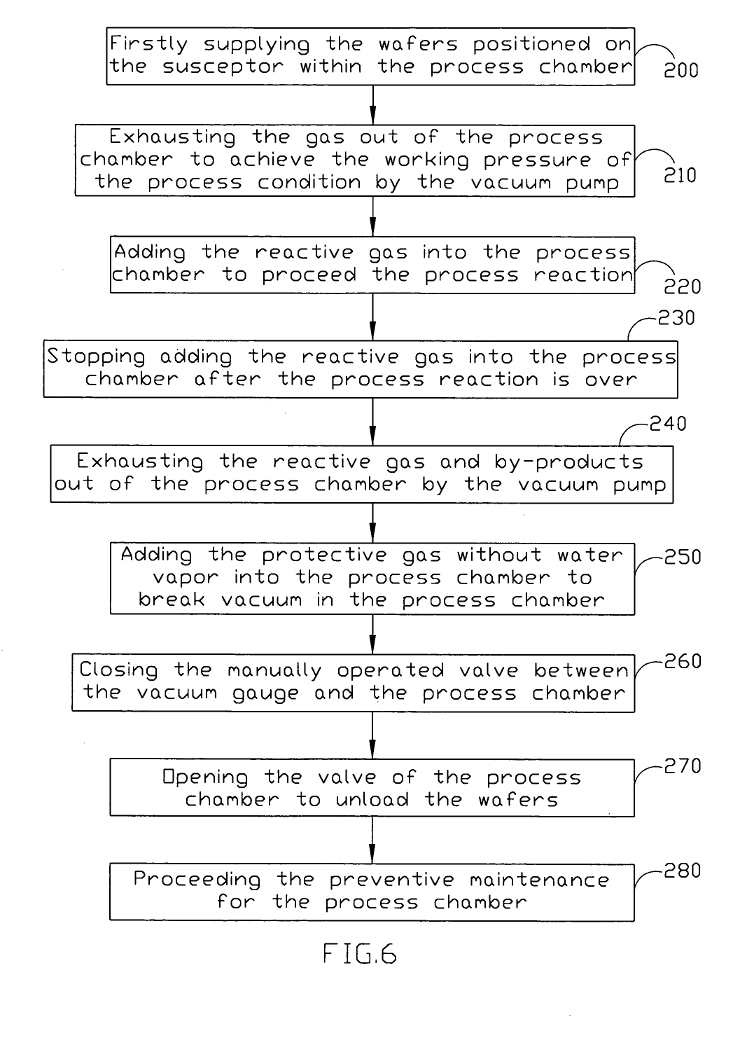

Finally, referring to FIG. 6, another preferred embodiment of the present invention is a flow chart of the preventive maintenance for preventing corrosion of the vacuum gauge, and its steps include: firstly supplying the wafers positioned on the susceptor within the process chamber (step 200), exhausting the gas out of the process chamber to achieve the working pressure of the process condition by the vacuum pump (step 210), adding the reactive gas into the process chamber to proceed the process reaction (step 220), stopping adding the reactive gas into the process chamber after the process reaction is over (step 230), exhausting the reactive gas and by-products out of the process chamber by the vacuum pump (step 240), adding the protective gas without water vapor into the process chamber to break vacuum in the process chamber (step 250), closing the manually operated valve between the vacuum gauge and the process chamber (step 260), opening the valve of the process chamber to unload the wafers (step 270), and proceeding the preventive maintenance for the process chamber (step 280). Herein the protective gas is added into the process chamber to break vacuum in the process chamber, the inner space of the vacuum gauge is full of the protective gas with equivalent pressure to the process chamber at the same time. When the pressure of the protective gas within the process chamber is equivalent to the atmospheric pressure, the manually operated valve is closed right now to isolate the vacuum gauge from the process chamber. Then the valve of the process chamber is opened to proceed the preventive maintenance of the process chamber. Because the pressure of the inner space of the vacuum gauge is equivalent to the pressure of the process chamber, the atmospheric water vapor of the process chamber will not flow into the inner space of the vacuum gauge due to a pressure differential between the vacuum gauge and the process chamber. The purpose of preventing corrosion of the vacuum gauge can be attained.

Above said preferred embodiment is only used to illustrate the present invention, not intended to limit the scope thereof. Many modifications of the preferred embodiment can be made without departing from the spirit of the present invention.

1. A vacuum process apparatus for preventing corrosion of a vacuum gauge, said apparatus comprising:
a process chamber which is used to proceed a vacuum process reaction;
a vacuum gauge which is connected to said process chamber;
a protective gas source without water vapor which supplys a protective gas without water vapor into said process chamber to break vacuum in said process chamber after said vacuum process reaction within said process chamber is over; and
an isolation device between said process chamber and said vacuum gauge is actuated to isolate said process chamber from said vacuum gauge in an atmospheric pressure state caused by said protective gas without water vapor to avoid a pressure differential between said process chamber and said vacuum gauge.

2. The apparatus of claim 1, wherein said vacuum gauge comprises a capacitance manometer.

3. The apparatus of claim 1, wherein said protective gas source without water vapor comprises nitrogen gas (N₂).

4. The apparatus of claim 1, wherein said vacuum process reaction comprises a plasma etching reaction.

5. The apparatus of claim 1, wherein said vacuum process reaction comprises a chemical vapor deposition reaction.

6. The apparatus of claim 1, wherein said isolation device comprises a valve.

7. The apparatus of claim 6, wherein said valve comprises a flexible gasket.

8. The apparatus of claim 7, wherein said flexible gasket comprises an O-ring.

9. The apparatus of claim 6, wherein said valve comprises a bellows.

10. The apparatus of claim 6, wherein said valve comprises a manually operated valve.

11. The apparatus of claim 6, wherein said valve comprises a pneumatically operated valve.

12. The apparatus of claim 6, wherein said valve comprises a solenoid valve.

13. A method for preventing corrosion of a vacuum gauge, said method comprising:
supplying a process chamber which is connected to a vacuum gauge;
adding a protective gas without water vapor into said process chamber to break vacuum in said process chamber after a vacuum process reaction within said process chamber is over; and
isolating said process chamber from said vacuum gauge in an atmospheric pressure state caused by said protective gas without water vapor to avoid a pressure differential between said process chamber and said vacuum gauge.

14. The method of claim 13, further comprising:
opening a valve of said process chamber to contact with an atmospheric condition.

15. The method of claim 13, wherein said vacuum gauge comprises a capacitance manometer.

16. The method of claim 13, wherein said protective gas without water vapor comprises nitrogen gas (N₂).

17. The method of claim 13, wherein said vacuum process reaction comprises a plasma etching reaction.

18. The method of claim 13, wherein said vacuum process reaction comprises a chemical vapor deposition reaction.
